(19) United States
(12) Patent Application Publication
(10) Pub. No.: US 2015/0212365 A1
(43) Pub. Date: Jul. 30, 2015

(54) LIQUID CRYSTAL DISPLAY DEVICE AND MANUFACTURING METHOD THEREOF

(71) Applicant: Samsung Display Co., Ltd., Yongin-City (KR)

(72) Inventors: Beong-Hun BEON, Hwaseong-si (KR); Dae Won KIM, Suwon-si (KR); Min Su KIM, Hwaseong-si (KR); Seung Beom PARK, Hwaseong-si (KR); Jung-Hun LEE, Seoul (KR); Yun JANG, Hwaseong-si (KR)

(21) Appl. No.: 14/476,290

(22) Filed: Sep. 3, 2014

(30) Foreign Application Priority Data
Jan. 29, 2014 (KR) 10-2014-0011527

(51) Int. Cl. G02F 1/1333; H01L 27/12; G02F 1/1341; G02F 1/1337; G02F 1/1368; G02F 1/1335

(52) U.S. Cl. CPC G02F 1/133377; G02F 1/1368; G02F 1/133345; G02F 1/133514; G02F 1/1341; G02F 1/133512; G02F 1/1337; H01L 27/1262

(57) ABSTRACT

A liquid crystal display includes a substrate including a plurality of pixel areas, a color filter disposed in each of the plurality of pixel areas, and a liquid crystal layer positioned on a pixel electrode and filling a microcavity. A height of the liquid crystal layer corresponding to the color filter having a first color is different from a height of the liquid crystal layer corresponding to the color filter having a second color.

### CROSS-REFERENCE TO RELATED APPLICATION

This application claims priority to and the benefit of Korean Patent Application No. 10-2014-0011527 filed in the Korean Intellectual Property Office on Jan. 29, 2014, the entire contents of which are incorporated herein by reference.

### BACKGROUND

(a) Technical Field

The present disclosure relates to a liquid crystal display and a manufacturing method thereof, and more particularly, to a liquid crystal display including a liquid crystal layer (comprising nanocrystals) disposed in a microcavity and a manufacturing method thereof.

(b) Description of the Related Art

A liquid crystal display is one of the most common types of flat panel displays currently in use. A liquid crystal display typically includes two sheets of display panels with field generating electrodes (such as a pixel electrode and a common electrode), and a liquid crystal layer interposed therebetween. The liquid crystal display generates an electric field in the liquid crystal layer by applying a voltage to the field generating electrodes, determines the direction of liquid crystal molecules of the liquid crystal layer based on the generated electric field, and controls polarization of incident light, thereby displaying images.

A liquid crystal display may be manufactured by forming a sacrificial layer with a photoresist, removing the sacrificial layer after coating a support member thereon, and filling a liquid crystal in an empty space formed by removing the sacrificial layer. The liquid crystal display is a display device and may be formed having an embedded microcavity (EM) structure (nanocrystal structure).

However, when the same voltage is applied to each subpixel by varying transmittance of light for each R, G, and B (red, green, and blue) color filter, a contrast ratio of the liquid crystal display may deteriorate due to a difference in transmittance. To control the different transmittance for each color filter, a different voltage may need to be applied to each color filter, and a separate voltage controlling unit for controlling the voltage may need to be provided.

The above information disclosed in this Background section is only to enhance understanding of the background of the inventive concept and therefore it may contain information that does not form prior art that is already known in this country to a person of ordinary skill in the art.

### SUMMARY

The inventive concept addresses at least the above issues relating to the control of light transmittance for different color filters in a liquid crystal display.

According to an exemplary embodiment of the inventive concept, a liquid crystal display is provided. The liquid crystal display includes: a substrate including a plurality of pixel areas; a thin film transistor disposed on the substrate in each of the plurality of pixel areas; a color filter disposed in each of the plurality of pixel areas; a pixel electrode electrically connected with a drain electrode of the thin film transistor; a liquid crystal layer positioned on the pixel electrode and filling a microcavity; a common electrode positioned on the pixel electrode and spaced apart from the pixel electrode by the microcavity; a roof layer positioned on the common electrode; an injection hole formed in the common electrode and the roof layer so as to expose a part of the microcavity; and an overcoat formed on the roof layer so as to cover the injection hole to seal the microcavity, wherein a height of the liquid crystal layer corresponding to the color filter having a first color is different from a height of the liquid crystal layer corresponding to the color filter having a second color.

In some embodiments, red, green, and blue color filters may be formed in each pixel area.

In some embodiments, the liquid crystal display may further include a light blocking member disposed between adjacent color filters.

In some embodiments, a height of the liquid crystal layer separately formed on each color filter may be defined by the following equation:

$$d = \frac{2}{m {λ}_{cf} Δ {n}_{lc}}$$

where d represents a width of the microcavity or the liquid crystal layer or a cell gap of the liquid crystal layer, λ_{cf} represents a wavelength of light passing through each color filter, Δn_{lc} represents a phase difference of the liquid crystal, and m represents an integer.

In some embodiments, the liquid crystal display may further include a first insulating layer positioned on the thin film transistor.

In some embodiments, the liquid crystal display may further include a second insulating layer positioned on the common electrode.

In some embodiments, the liquid crystal display may further include a first alignment layer and a second alignment layer disposed on the pixel electrode and the common electrode, respectively.

In some embodiments, the first alignment layer and the second alignment layer may be vertical alignment layers.

In some embodiments, the liquid crystal display may further include a third insulating layer formed on the roof layer.

According to another exemplary embodiment of the inventive concept, a method of manufacturing a liquid crystal display is provided. The method includes: forming a thin film transistor on a substrate in each of a plurality of pixel areas; forming a color filter in each of the plurality of pixel areas; forming a pixel electrode electrically connected with a drain electrode of the thin film transistor; forming a sacrificial layer on the pixel electrode so that a height of the sacrificial layer corresponding to the color filter having a first color is different from a height of the sacrificial layer corresponding to the color filter having a second color; forming a common electrode on the sacrificial layer; forming a roof layer on the common electrode; exposing the sacrificial layer; forming, by removing the exposed sacrificial layer, a microcavity separately for each color filter between the pixel electrode and the common electrode; forming a liquid crystal layer by injecting a liquid crystal material into the microcavity; and forming an overcoat on the roof layer to seal the microcavity.

In some embodiments, the sacrificial layer may be formed by an inkjet method.

In some embodiments, red, green, and blue color filters may be formed in each pixel area.

In some embodiments, the method may further include forming a light blocking member between the respective color filters.

In some embodiments, a height of the liquid crystal layer separately formed on each color filter may be defined by the following equation:

$$d = \frac{2}{m {λ}_{cf} Δ {n}_{lc}}$$

where d represents a height of the liquid crystal layer or a cell gap of the liquid crystal layer, λ_{cf} represents a wavelength of light passing through each color filter, Δn_{lc} represents a phase difference of the liquid crystal, and m represents an integer.

In some embodiments, the method may further include forming a first insulating layer on the thin film transistor.

In some embodiments, the method may further include forming a second insulating layer on the common electrode.

In some embodiments, the method may further include forming a first alignment layer and a second alignment layer on the pixel electrode and the common electrode, respectively.

In some embodiments, the first alignment layer and the second alignment layer may be vertical alignment layers.

In some embodiments, the method may further include forming a third insulating layer on the roof layer.

According to the inventive concept, in order to control different transmittance of light for each color filter, a different cell gap for each color filter is formed, so as to improve the contrast ratio of the liquid crystal display.

Furthermore, since different transmittance of light for each color filter may be controlled through a cell gap, a voltage controlling unit for controlling transmittance may be omitted, thereby allowing manufacturing costs of the liquid crystal display to be reduced.

### BRIEF DESCRIPTION OF THE DRAWINGS

FIG. 1 is a plan view illustrating a liquid crystal display according to an exemplary embodiment of the inventive concept.

FIG. 2 is a plan view illustrating a pixel of the liquid crystal display of FIG. 1 according to an exemplary embodiment of the inventive concept.

FIG. 3 is a cross-sectional view taken along line III-III of FIG. 1.

FIG. 4 is a cross-sectional view taken along line IV-IV of FIG. 1.

FIG. 5 is a cross-sectional view taken along line V-V of FIG. 1.

FIGS. 6 to 11 are diagrams sequentially illustrating a method of manufacturing a liquid crystal display according to an exemplary embodiment of the inventive concept.

FIG. 12 compares the contrast ratios between an exemplary liquid crystal display and a conventional liquid crystal display.

FIG. 13 is a cross-sectional view of a liquid crystal display according to another exemplary embodiment of the inventive concept.

### DETAILED DESCRIPTION

The inventive concept will be described more fully herein with reference to the accompanying drawings, in which exemplary embodiments of the inventive concept are shown. As those skilled in the art would realize, the described embodiments may be modified in various different ways without departing from the spirit or scope of the inventive concept.

In the drawings, the thickness of layers, films, panels, regions, etc., may be exaggerated for clarity. Like reference numerals designate like elements throughout the specification. It will be understood that when an element such as a layer, film, region, or substrate is referred to as being “on” another element, it can be directly on the other element, or with one or more intervening elements being present. In contrast, when an element is referred to as being “directly on” another element, there are no intervening elements present.

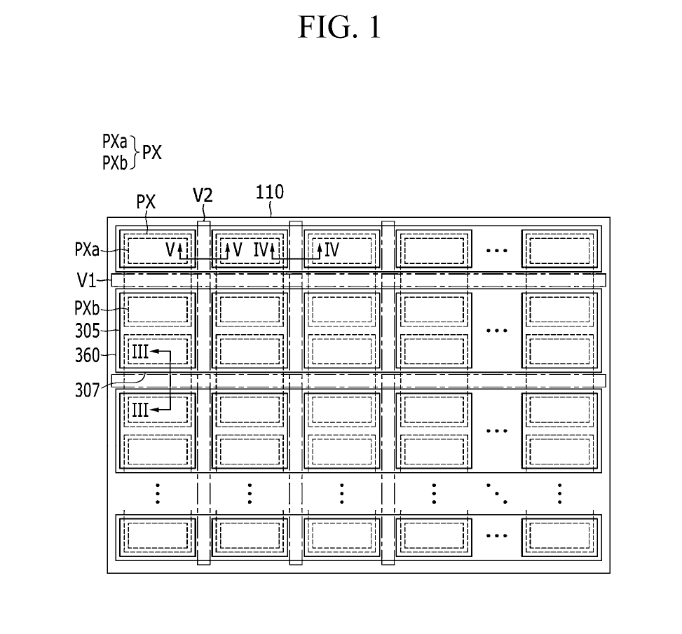

First, a liquid crystal display according to an exemplary embodiment of the inventive concept will be described with reference to FIG. 1.

FIG. 1 is a plan view illustrating an exemplary liquid crystal display. To avoid obscuring the inventive concept, FIG. 1 focuses on some of the key constituent elements of the exemplary liquid crystal display.

Referring to FIG. 1, the liquid crystal display includes a substrate 110 made of a material such as glass or plastic, and a roof layer 360 formed on the substrate 110.

The substrate 110 includes a plurality of pixel areas PX. The plurality of pixel areas PX are disposed in a matrix form which includes a plurality of pixel rows and a plurality of pixel columns. Each pixel area PX may include a first subpixel area PXa and a second subpixel area PXb. The first subpixel area PXa and the second subpixel area PXb may be vertically disposed.

A first valley V1 is positioned between the first subpixel area PXa and the second subpixel area PXb in a pixel row direction, and a second valley V2 is positioned between a plurality of pixel columns.

The roof layer 360 is formed in a pixel row direction. In this case, a portion of the roof layer 360 is removed at the first valley V1 and thus an injection hole 307 is formed so that a constituent element positioned below the roof layer 360 is exposed to the outside.

Each roof layer 360 is separated from the substrate 110 between adjacent second valleys V2 so as to form the microcavity 305. Further, each roof layer 360 is attached to the substrate 110 at the second valley V2 so as to cover both sides of the microcavity 305.

It should be noted that the above-described structure of the liquid crystal display is merely exemplary and that the structure of the liquid crystal display may be modified in various ways. For example, the layout of the pixel area PX, the first valley V1, and the second valley V2 may be modified such that the plurality of roof layers 360 are connected to each other at the first valley V1, a portion of each roof layer 360 is separated from the substrate 110 at the second valley V2, and adjacent microcavities 305 are connected to each other.

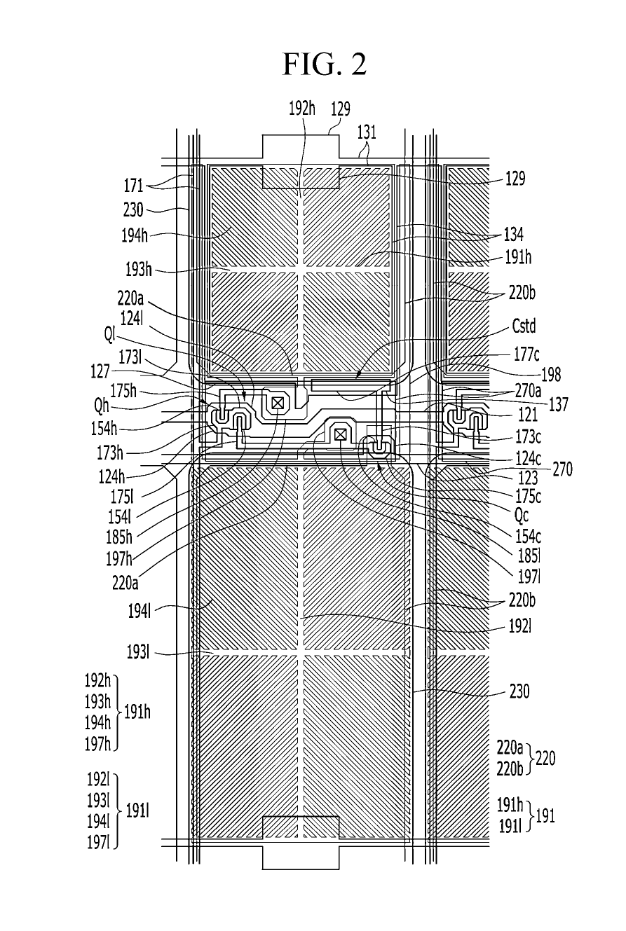

Next, a pixel of the liquid crystal display of FIG. 1 according to an exemplary embodiment of the inventive concept will be described in detail with reference to FIGS. 2 to 5.

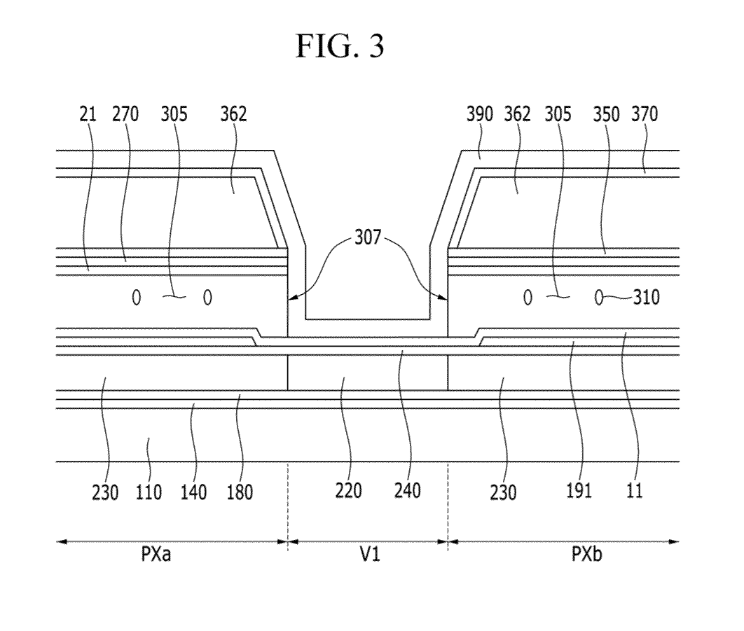

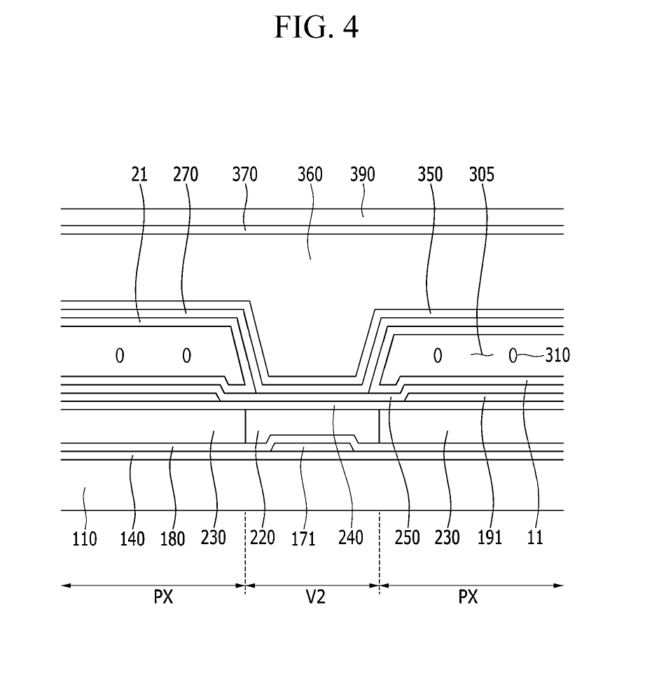

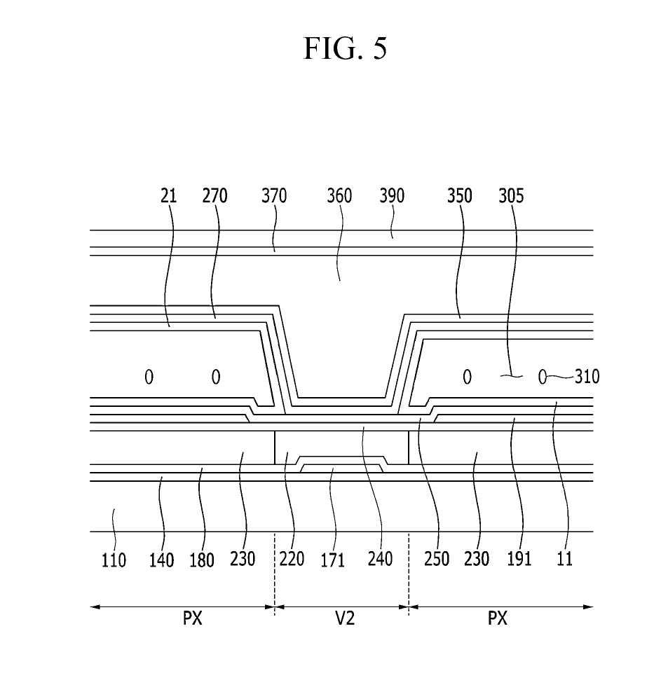

FIG. 2 is a plan view illustrating a pixel of the liquid crystal display of FIG. 1 according to an exemplary embodiment of the inventive concept, FIG. 3 is a cross-sectional view taken along line III-III of FIG. 1, FIG. 4 is a cross-sectional view taken along line IV-IV of FIG. 1, and FIG. 5 is a cross-sectional view taken along line V-V of FIG. 1.

Referring to FIGS. 2 to 5, a plurality of gate conductors including a plurality of gate lines 121, a plurality of step-down gate lines 123, and a plurality of storage electrode lines 131 are formed on the substrate 110.

The gate line 121 and the step-down gate line 123 transfer gate signals and mainly extend in a horizontal direction. The gate conductor further includes a first gate electrode 124h and a second gate electrode 124I protruding upward and downward respectively from the gate line 121, and a third gate electrode 124c protruding upward from the step-down gate line 123. The first gate electrode 124h and the second gate electrode 124I are connected with each other to form a protrusion. The protrusion formed by the first, second, and third gate electrodes 124h, 124l, and 124c may be modified in various ways.

The storage electrode line 131 transfers a predetermined voltage (such as a common voltage Vcom) and mainly extends in a horizontal direction. The storage electrode line 131 includes storage electrodes 129 protruding both upward and downward, a pair of vertical portions 134 extending downward to be substantially perpendicular to the gate line 121, and a horizontal portion 127 connecting the ends of the pair of vertical portions 134. The horizontal portion 127 includes a capacitor electrode 137 extending downward.

A gate insulating layer 140 is formed on the gate conductor 121, 123, 124h, 124l, 124c, and 131. The gate insulating layer 140 may be made of an inorganic insulating material such as silicon nitride (SiNx) or silicon oxide (SiOx). The gate insulating layer 140 may be formed as a single layer or a multiple layered structure.

A first semiconductor 154h, a second semiconductor 154l, and a third semiconductor 154c are formed on the gate insulating layer 140. The first semiconductor 154h may be positioned on the first gate electrode 124h, the second semiconductor 154l may be positioned on the second gate electrode 124I, and the third semiconductor 154c may be positioned on the third gate electrode 124c. The first semiconductor 154h and the second semiconductor 154l may be connected to each other, and the second semiconductor 154l and the third semiconductor 154c may be connected to each other. Further, the first semiconductor 154h may extend to a lower portion of the data line 171. The first to third semiconductors 154h, 154l, and 154c may be made of amorphous silicon, polycrystalline silicon, metal oxide, or other similar materials.

Ohmic contacts (not illustrated) may be further formed on the first to third semiconductors 154h, 154l, and 154c, respectively. The ohmic contacts may be made of silicide, or a material doped with a high concentration of an n-type impurity (e.g., n+ hydrogenated amorphous silicon).

Data conductors are formed on the first to third semiconductors 154h, 154l, and 154c. The data conductors include a data line 171, a first source electrode 173h, a second source electrode 173l, a third source electrode 173c, a first drain electrode 175h, a second drain electrode 175l, and a third drain electrode 175c.

The data lines 171 transfer data signals and mainly extend in a vertical direction crossing the gate lines 121 and the step-down gate lines 123. Each data line 171 includes a first source electrode 173h and a second source electrode 173l connected with each other, and extending respectively toward the first gate electrode 124h and the second gate electrode 124l.

Each of a first drain electrode 175h, a second drain electrode 175l, and a third drain electrode 175c includes a wide end portion and a rod-shaped end portion. The rod-shaped end portions of the first drain electrode 175h and the second drain electrode 175l are partially surrounded by the first source electrode 173h and the second source electrode 173l. The wide end portion of the second drain electrode 175l extends to form a third source electrode 173c which is bent in the shape of the letter ‘U’. A wide end portion 177c of the third drain electrode 175c overlaps with the capacitor electrode 137 to form a step-down capacitor Cstd, and the rod-shaped end portion of the third drain electrode 175c is partially surrounded by the third source electrode 173c.

The first gate electrode 124h, the first source electrode 173h, and the first drain electrode 175h, together with the first semiconductor 154h, collectively constitute a first thin film transistor Qh. The second gate electrode 124I, the second source electrode 173I, and the second drain electrode 175I, together with the second semiconductor 154I, collectively constitute a second thin film transistor QI. The third gate electrode 124c, the third source electrode 173c, and the third drain electrode 175c, together with the third semiconductor 154c, collectively constitute a third thin film transistor Qc.

The first semiconductor 154h, the second semiconductor 154I, and the third semiconductor 154c are connected to each other in a stripe shape, and may have substantially the same planar shape as the data conductors 171, 173h, 173I, 173c, 175h, 175I, and 175c and the ohmic contacts disposed therebelow, except for the channel regions between the respective source electrodes 173h, 173I, and 173c and the drain electrodes 175h, 173I, and 175c.

An exposed portion of the first semiconductor 154h (which is not covered by the first source electrode 173h and the first drain electrode 175h) is disposed between the first source electrode 173h and the first drain electrode 175h. An exposed portion of the second semiconductor 154I (which is not covered by the second source electrode 173I and the second drain electrode 175I) is disposed between the second source electrode 173I and the second drain electrode 175I. An exposed portion of the third semiconductor 154c (which is not covered by the third source electrode 173c and the third drain electrode 175c) is disposed between the third source electrode 173c and the third drain electrode 175c.

A passivation layer 180 is formed on the data conductors 171, 173h, 173l, 173c, 175h, 175l, and 175c, and the semiconductors 154h, 154l, and 154c exposed between the respective source electrodes 173h/173l/173c and the drain electrodes 175h/175l/175c. The passivation layer 180 may be made of an organic insulating material or an inorganic insulating material. The passivation layer 180 may be formed as a single layer or a multiple layered structure.

A color filter 230 is formed on the passivation layer 180 in each pixel area PX. Each color filter 230 may display one of primary colors (such as the three primary colors red, green, and blue). However, the color filter 230 is not limited to the three primary colors red, green and blue, but may also display one of cyan, magenta, yellow, and white-based colors. In some embodiments (not illustrated), the color filter 230 may be elongated in a column direction along a space between adjacent data lines 171.

A light blocking member 220 is formed in a region between adjacent color filters 230. The light blocking member 220 is formed on a boundary of the pixel area PX and the thin film transistor to prevent light leakage. The color filter 230 is formed in each of the first subpixel area PXa and the second subpixel area PXb, and the light blocking member 220 may be formed between the first subpixel area PXa and the second subpixel area PXb.

The light blocking member 220 includes a horizontal light blocking member 220a extending along the gate line 121 and the step-down gate line 123, and covering regions in which the first thin film transistor Qh, the second thin film transistor QI, and the third thin film transistor Qc are positioned. The light blocking member 220 also includes a vertical light blocking member 220b extending along the data line 171. That is, the horizontal light blocking member 220a may be formed at the first valley V1, and the vertical light blocking member 220b may be formed at the second valley V2. The color filter 230 and the light blocking member 220 may overlap with each other in a partial region.

In some particular embodiments, the color filter 230 may be formed on the microcavity 305.

A first insulating layer 240 may be formed on the color filter 230 and the light blocking member 220. The first insulating layer 240 may be made of an inorganic insulating material such as silicon nitride (SiNx), silicon oxide (SiOx), or silicon oxynitride (SiOxNy). The first insulating layer 240 serves to protect the color filter 230 and the light blocking member 220. In some particular embodiments, the first insulating layer 240 may be omitted.

A plurality of first contact holes 185h and a plurality of second contact holes 185l, which expose the wide end portion of the first drain electrode 175h and the wide end portion of the second drain electrode 175l, respectively, are formed in the first insulating layer 240, the light blocking member 220, and the passivation layer 180.

A pixel electrode 191 is formed on the first insulating layer 240. The pixel electrode 191 may be made of a transparent metal material such as indium tin oxide (ITO) or indium zinc oxide (IZO).

The pixel electrode 191 includes the first subpixel electrode 191h and the second subpixel electrode 191l separated from each other with the gate line 121 and the step-down gate line 123 disposed therebetween. The first subpixel electrode 191h and the second subpixel electrode 191l are respectively disposed above and below the pixel area PX with reference to the gate line 121 and the step-down gate line 123, so as to be disposed adjacent to each other in a column direction. That is, the first subpixel electrode 191h and the second subpixel electrode 191l are separated from each other with the first valley V1 disposed therebetween, the first subpixel electrode 191h is positioned in the first subpixel area PXa, and the second subpixel electrode 191l is positioned in the second subpixel area PXb.

The first subpixel electrode 191h and the second subpixel electrode 191l are connected with the first drain electrode 175h and the second drain electrode 175l through the first contact hole 185h and the second contact hole 185l, respectively. Accordingly, when the first thin film transistor Qh and the second thin film transistor Ql are turned on, the first thin film transistor Qh and the second thin film transistor Ql receive data voltages from the first drain electrode 175h and the second drain electrode 175l.

Each of the first subpixel electrode 191h and the second subpixel electrode 191l has a quadrangle shape. The first subpixel electrode 191h and the second subpixel electrode 191l include cross stems including horizontal stems 193h and 193l and vertical stems 192h and 192l crossing the respective horizontal stems 193h and 193l. Further, the first subpixel electrode 191h and the second subpixel electrode 191l include a plurality of minute branches 194h and 194l, and protrusions 197h and 197l protruding downward or upward from the respective edges of the subpixel electrodes 194h and 194l.

The pixel electrode 191 is divided into four subregions by the horizontal stems 193h and 193l and the vertical stems 192h and 192l. The minute branches 194h and 194l extend obliquely from the horizontal stems 193h and 193l and the vertical stems 192h and 192l, and the extending direction may form an angle of approximately 45 degrees or 135 degrees with the gate line 121 or the horizontal stems 193h and 193l. Further, the directions in which the minute branches 194h and 194l of the two adjacent subregions extend may be perpendicular to each other.

In an exemplary embodiment, the first subpixel electrode 191h further includes an outer stem surrounding the outside of the first subpixel electrode 191h, and the second subpixel electrode 191I further includes horizontal portions positioned at an upper end and a lower end, and left and right vertical portions 198 positioned at the left and the right of the first subpixel electrode 191h. The left and right vertical portions 198 may prevent capacitive coupling, that is, coupling between the data line 171 and the first subpixel electrode 191h.

It should be noted that the layout of the pixel area, the structure of the thin film transistor, and the shape of the pixel electrode described above are merely exemplary, and that the inventive concept is not limited thereto and may be modified in various ways.

A common electrode 270 is formed on the pixel electrode 191 so as to be spaced apart from the pixel electrode 191 at a predetermined distance. A microcavity 305 is formed between the pixel electrode 191 and the common electrode 270. That is, the microcavity 305 is surrounded by the pixel electrode 191 and the common electrode 270.

According to an exemplary embodiment of the inventive concept, the microcavity 305 of the liquid crystal display has a different width for each color filter 230.

As previously described, the color filters may be based on the three primary colors red, green, and blue. When a microcavity formed on each color filter has a same width and the transmittance of light for each red, green, and blue color filter is varied, a contrast ratio of the liquid crystal display may deteriorate. As a result, a voltage controlling unit may need to be separately provided for controlling different transmittance for each color filter, for controlling and supplying a voltage for each color filter to prevent deterioration of the contrast ratio, and for controlling the voltage applied for each color filter.

The inventive concept can improve the contrast ratio of the liquid crystal display and eliminate the need to have a separate voltage controlling unit. According to the inventive concept, the liquid crystal display can control transmittance of light for each color filter 230 by varying a width of the microcavity 305 formed on each color filter 230, without the need to control the voltage applied to each color filter 230.

Thus, the liquid crystal display according to the inventive concept may provide the same transmittance of light for each color filter 230 even though the same voltage is applied for each color filter 230, without requiring a separate voltage controlling unit.

Referring to FIGS. 4 and 5, the width of the microcavity 305 may be increased toward a left pixel of the liquid crystal display, but the inventive concept is not limited thereto.

The width of each microcavity 305 may be defined by the following Equation 1.

$$d = \frac{2}{m {λ}_{cf} Δ {n}_{lc}} \qquad [ Equation 1 ]$$

Referring to Equation 1, d represents a width of the microcavity 305 or the liquid crystal layer or a cell gap of the liquid crystal layer, λ_{cf} represents a wavelength of light passing through each color filter, Δn_{lc} represents a phase difference of the liquid crystal, and m represents an integer.

For example, when a target wavelength of the liquid crystal display is 589 nm, a width of the microcavity 305 of a blue color filter having a wavelength of 450 nm may be 2.29 μm, a width of the microcavity 305 of a green color filter having a wavelength of 550 nm may be 2.8 μm, and a width of the microcavity 305 of a red color filter having a wavelength of 650 nm may be 3.31 μm.

The width of the microcavity 305 may be modified in various ways according to Equation 1, and an area of the microcavity 305 may also be modified in various ways according to a size and resolution of the liquid crystal display.

The common electrode 270 may be made of a transparent metal material such as indium tin oxide (ITO) or indium zinc oxide (IZO). A predetermined voltage may be applied to the common electrode 270, and an electric field may be generated between the pixel electrode 191 and the common electrode 270.

A first alignment layer 11 is formed on the pixel electrode 191. The first alignment layer 11 may also be formed directly on a portion of the first insulating layer 240 which is not covered by the pixel electrode 191.

A second alignment layer 21 is formed below the common electrode 270 so as to face the first alignment layer 11.

The first alignment layer 11 and the second alignment layer 21 may be formed by vertical alignment layers, and may be made of alignment materials such as polyamic acid, polysiloxane, or polyimide. The first and second alignment layers 11 and 21 may be connected to each other at an edge of the pixel area PX.

A liquid crystal layer comprising liquid crystal molecules 310 is formed in the microcavity 305 positioned between the pixel electrode 191 and the common electrode 270. The liquid crystal molecules 310 have negative dielectric anisotropy, and may align in a direction perpendicular to the substrate 110 when the electric field is not applied. That is, vertical alignment may be performed.

The first subpixel electrode 191h and the second subpixel electrode 191l (to which the data voltage is applied) generate an electric field together with a common electrode 270. The electric field determines the directions of the liquid crystal molecules 310 positioned in the microcavity 305 between the two electrodes 191 and 270. As such, luminance of light passing through the liquid crystal layer varies according to the determined directions of the liquid crystal molecules 310.

A second insulating layer 350 may be further formed on the common electrode 270. The second insulating layer 350 may be made of an inorganic insulating material such as silicon nitride (SiNx), silicon oxide (SiOx), or silicon oxynitride (SiOxNy). In some particular embodiments, the second insulating layer 350 may be omitted.

A roof layer 360 is formed on the second insulating layer 350. The roof layer 360 may be made of an organic material. The microcavity 305 is formed below the roof layer 360, and the roof layer 360 is hardened by a curing process to maintain the shape of the microcavity 305. That is, the roof layer 360 is spaced apart from the pixel electrode 191 with the microcavity 305 disposed therebetween.

The roof layer 360 is formed in each pixel area PX along a pixel row and the second valley V2, and is not formed in the first valley V1. That is, the roof layer 360 is not formed between the first subpixel area PXa and the second subpixel area PXb. The microcavity 305 is formed below each roof layer 360 in each of the first subpixel area PXa and the second subpixel area PXb. In the second valley V2, the microcavity 305 is not formed below the roof layer 360, but is attached to the substrate 110. Accordingly, a thickness of the roof layer 360 positioned at the second valley V2 may be greater than a thickness of the roof layer 360 positioned in each of the first subpixel area PXa and the second subpixel area PXb. The upper surface and both sides of the microcavity 305 are covered by the roof layer 360.

An injection hole 307 exposing a part of the microcavity 305 is formed in the common electrode 270, the second insulating layer 350, and the roof layer 360. A plurality of injection holes 307 may face each other at the edges of the first subpixel area PXa and the second subpixel area PXb. That is, the injection holes 307 may be disposed corresponding to the lower side of the first subpixel area PXa and the upper side of the second subpixel area PXb so as to expose a side of the microcavity 305. Since the microcavity 305 is exposed by the injection hole 307, an aligning agent or a liquid crystal material may be injected into the microcavity 305 through the injection hole 307.

An overcoat 390 may be formed on the third insulating layer 370. The overcoat 390 is formed covering the injection hole 307 (where a part of the microcavity 305 is exposed to the outside). That is, the overcoat 390 may seal the microcavity 305 so that the liquid crystal molecules 310 formed in the microcavity 305 are not discharged outside. Since the overcoat 390 contacts the liquid crystal molecules 310, the overcoat 390 may be made of a material which does not react with liquid crystal molecules 310. For example, the overcoat 390 may be made of parylene and the like.

The overcoat 390 may be formed as a multilayer structure (such as a double layer or a triple layer). The double layer includes two layers made of different materials. The triple layer includes three layers, and materials of adjacent layers are different from each other. For example, the overcoat 390 may include a layer made of an organic insulating material and a layer made of an inorganic insulating material.

Although not illustrated, polarizers may be further formed on upper and lower sides of the display device. The polarizers may include a first polarizer and a second polarizer. The first polarizer may be attached onto the lower side of the substrate 110, and the second polarizer may be attached onto the overcoat 390.

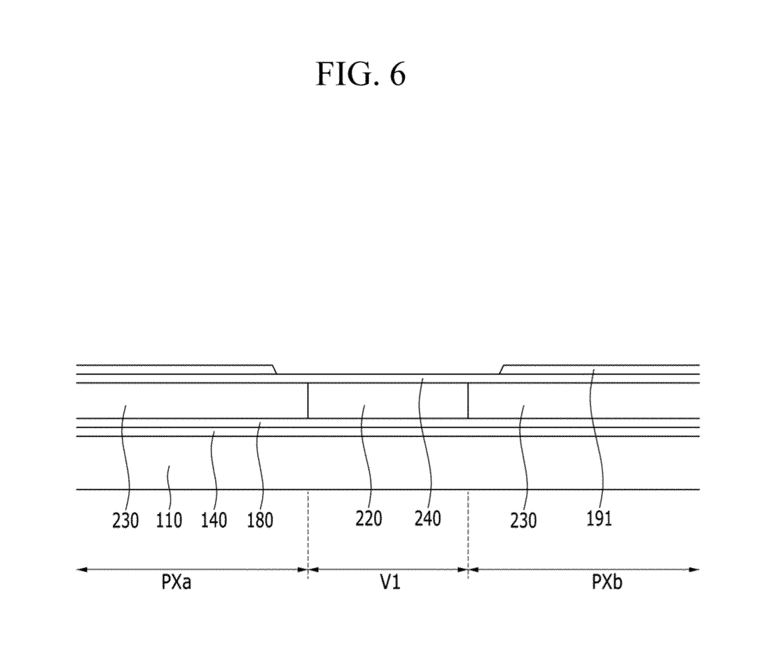

Next, a method of manufacturing a liquid crystal display according to an exemplary embodiment of the inventive concept will be described in detail with reference to FIGS. 6 to 11.

FIGS. 6 to 11 are diagrams sequentially illustrating a method of manufacturing a liquid crystal display according to an exemplary embodiment of the inventive concept.

First, a gate line 121 and a step-down gate line 123 (not shown) extending in one direction are formed on a substrate 110. The substrate 110 may be made of glass or plastic. A first gate electrode 124h, a second gate electrode 124l, and a third gate electrode 124c (not shown) protruding from the gate line 121 are also formed on the substrate 110.

Further, a storage electrode line 131 (not shown) may be formed so as to be spaced apart from the gate line 121, the step-down gate line 123, and the first to third gate electrodes 124h, 124l, and 124c.

Next, a gate insulating layer 140 is formed on the entire surface of the substrate 110 over the gate line 121, the step-down gate line 123, the first to third gate electrodes 124h, 124l, and 124c, and the storage electrode line 131. The gate insulating layer 140 may include an inorganic insulating material such as silicon oxide (SiOx) or silicon nitride (SiNx). The gate insulating layer 140 may be formed as a single layer or a multiple layered structure.

Next, a first semiconductor 154h, a second semiconductor 154l, and a third semiconductor 154c are formed by depositing a semiconductor material (such as amorphous silicon, polycrystalline silicon, or metal oxide) on the gate insulating layer 140 and then patterning the deposited semiconductor material. The first semiconductor 154h may be positioned on the first gate electrode 124h, the second semiconductor 154l may be positioned on the second gate electrode 124I, and the third semiconductor 154c may be positioned on the third gate electrode 124c.

Next, a data line 171 extending in the other direction (opposite to the gate lines) is formed by depositing a metal material and then patterning the deposited metal material. The metal material may be formed as a single layer or a multiple layered structure.

Further, a first source electrode 173h protruding above the first gate electrode 124h from the data line 171, and a first drain electrode 175h spaced apart from the first source electrode 173h, are formed together. Further, a second source electrode 173l connected with the first source electrode 173h, and a second drain electrode 175l spaced apart from the second source electrode 173l, are formed together. Further, a third source electrode 173c extending from the second drain electrode 175l, and a third drain electrode 175c spaced apart from the third source electrode 173c, are formed together.

The first to third semiconductors 154h, 154l, and 154c, the data line 171, the first to third source electrodes 173h, 173l, and 173c, and the first to third drain electrodes 175h, 175l, and 175c may be formed by sequentially depositing a semiconductor material and a metal material and then patterning the semiconductor material and the metal material at the same time. In this case, the first semiconductor 154h may extend to the lower portion of the data line 171.

The first/second/third gate electrodes 124h/124l/124c, the first/second/third source electrodes 173h/173l/173c, and the first/second/third drain electrodes 175h/175l/175c, together with the first/second/third semiconductors 154h/154l/154c, collectively constitute the first/second/third thin film transistors (TFTs) Qh/Ql/Qc, respectively.

Next, a passivation layer 180 is formed on the data line 171, the first to third source electrodes 173h, 173l, and 173c, the first to third drain electrodes 175h, 175l, and 175c, and the semiconductors 154h, 154l, and 154c exposed between the source electrodes 173h/173l/173c and the respective drain electrodes 175h/175l/175c. The passivation layer 180 may be made of an organic insulating material or an inorganic insulating material, and may be formed as a single layer or a multiple layered structure.

Next, a color filter 230 is formed in each pixel area PX on the passivation layer 180. The color filter 230 is formed in each of the first subpixel area PXa and the second subpixel area PXb, and is not be formed at the first valley V1. Further, the color filters 230 having the same color may be formed in a column direction of the plurality of pixel areas PX. When forming the color filters 230 having three colors, a first colored color filter 230 may first be formed and then a second colored color filter 230 may be formed by shifting a mask. After the second colored color filter 230 is formed, a third colored color filter 230 may be formed by shifting a mask.

Next, a light blocking member 220 is formed on a boundary of each pixel area PX on the passivation layer 180 and the thin film transistor. The light blocking member 220 may be formed at the first valley V1 positioned between the first subpixel area PXa and the second subpixel area PXb.

As described above, the light blocking member 220 is formed after forming the color filters 230. However, the inventive concept is not limited thereto. In some embodiments, the light blocking member 220 may be formed before forming the color filters 230.

As described above, the color filter 230 may be formed on the microcavity 305.

Next, a first insulating layer 240 made of an inorganic insulating material (such as silicon nitride (SiNx), silicon oxide (SiOx), or silicon oxynitride (SiOxNy)) is formed on the color filter 230 and the light blocking member 220.

Next, a first contact hole 185h (not shown) is formed by etching the passivation layer 180, the first light blocking member 220, and the first insulating layer 240 so as to expose a part of the first drain electrode 175h, and a second contact hole 185l (not shown) is formed so as to expose a part of the second drain electrode 175l.

Next, a first subpixel electrode 191h is formed in the first subpixel area PXa, and a second subpixel electrode 191l is formed in the second subpixel area PXb, by depositing and patterning a transparent metal material (such as indium tin oxide (ITO) or indium zinc oxide (IZO)) on the first insulating layer 240. The first subpixel electrode 191h and the second subpixel electrode 191l are separated from each other with the first valley V1 disposed therebetween. The first subpixel electrode 191h is connected with the first drain electrode 175h through the first contact hole 185h, and the second subpixel electrode 191l is connected to the second drain electrode 175l through the second contact hole 185l.

Horizontal stems 193h and 193l, and vertical stems 192h and 192l crossing the horizontal stems 193h and 193l, are formed in the first subpixel electrode 191h and the second subpixel electrode 191l, respectively. Further, a plurality of minute branches 194h and 194l are formed extending obliquely from the horizontal stems 193h and 193l and the vertical stems 192h and 192l.

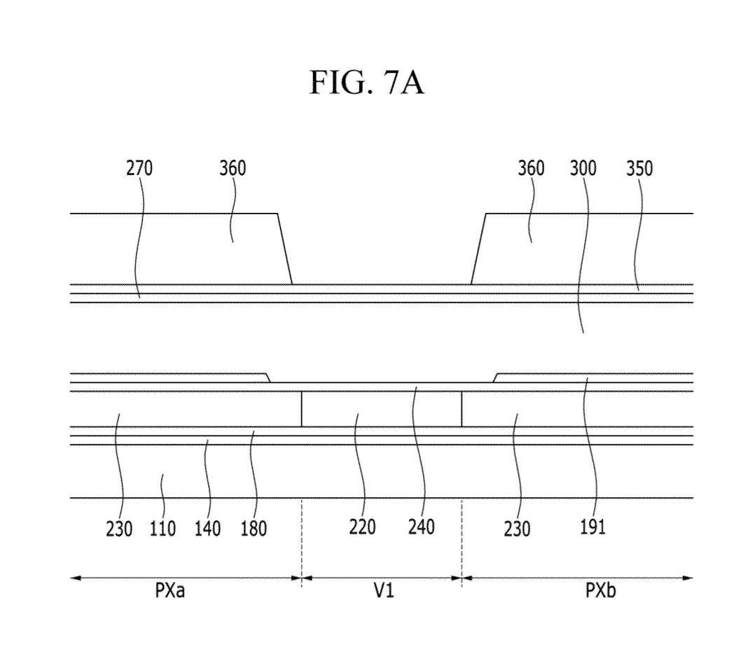

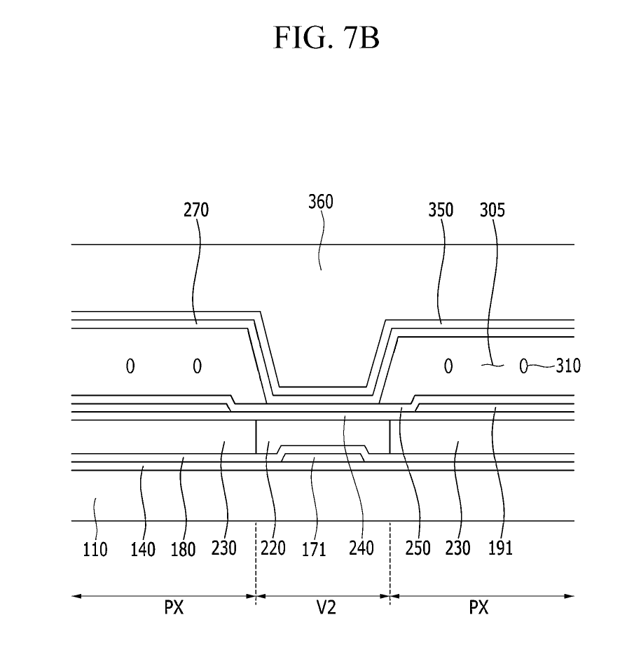

As illustrated in FIG. 7A, a sacrificial layer 300 is formed by coating a photosensitive organic material on the pixel electrode 191 and performing a photolithography process. In some embodiments, the sacrificial layer 300 may be formed by an inkjet method instead of a photolithography process.

A plurality of sacrificial layers 300 are connected to each other along the plurality of pixel columns. That is, the sacrificial layers 300 are formed covering each pixel area PX and the first valley V1 positioned between the first subpixel area PXa and the second subpixel area PXb.

According to an exemplary embodiment of the inventive concept, the sacrificial layer 300 of the liquid crystal display has a different width for each color filter 230.

As previously described, the color filters may be based on the three primary colors red, green, and blue. When the microcavity 300 formed on each color filter 230 has the same width and the transmittance of light for each red, green, and blue color filter 230 is varied, a contrast ratio of the liquid crystal display may deteriorate. As a result, a voltage controlling unit may need to be separately provided for controlling different transmittance for each color filter 230, for controlling and supplying a voltage for each color filter 230 to prevent deterioration of the contrast ratio, and for controlling the voltage applied for each color filter 230.

According to an exemplary embodiment of the inventive concept, the transmittance of light may be controlled for each color filter 230 by adjusting the width of the microcavity 305 for each color filter 230. Specifically, the transmittance of light may be controlled for each color filter 230 by varying the width of the sacrificial layer 300 formed on each color filter 230 for each color filter 230.

Referring to FIG. 7B, the width of the sacrificial layer 300 may be increased toward a left pixel of the liquid crystal display, but the inventive concept is not limited thereto.

The width of each sacrificial layer 300 may be defined by the following Equation 1.

$$d = \frac{2}{m {λ}_{cf} Δ {n}_{lc}} \qquad [ Equation 1 ]$$

Referring to Equation 1, d represents a width of the microcavity 305 or the liquid crystal layer or a cell gap of the liquid crystal layer, λ_{cf} represents a wavelength of light passing through each color filter, Δn_{lc} represents a phase difference of the liquid crystal, and m represents an integer.

For example, when a target wavelength of the liquid crystal display is 589 nm, a width of the sacrificial layer 300 of a blue color filter having a wavelength of 450 nm may be 2.29 μm, a width of the sacrificial layer 300 of a green color filter having a wavelength of 550 nm may be 2.8 μm, and a width of the sacrificial layer 300 of a red color filter having a wavelength of 650 nm may be 3.31 μm.

The width of the sacrificial layer 300 may be modified in various ways according to Equation 1, and an area of the sacrificial layer 300 may also be modified in various ways according to a size and resolution of the liquid crystal display.

Next, a common electrode 270 is formed by depositing a transparent metal material (such as indium tin oxide (ITO) or indium zinc oxide (IZO)) on the sacrificial layer 300.

Next, a second insulating layer 350 may be formed on the common electrode 270. The second insulating layer 350 may be made of an inorganic insulating material such as silicon nitride (SiNx), silicon oxide (SiOx), or silicon oxynitride (SiOxNy).

Next, a roof layer 360 is formed by coating and patterning an organic material on the second insulating layer 350. In this case, the organic material may be patterned by removing a portion of the organic material positioned at the first valley V1. As a result, the roof layers 360 may be connected to each other along a plurality of pixel rows.

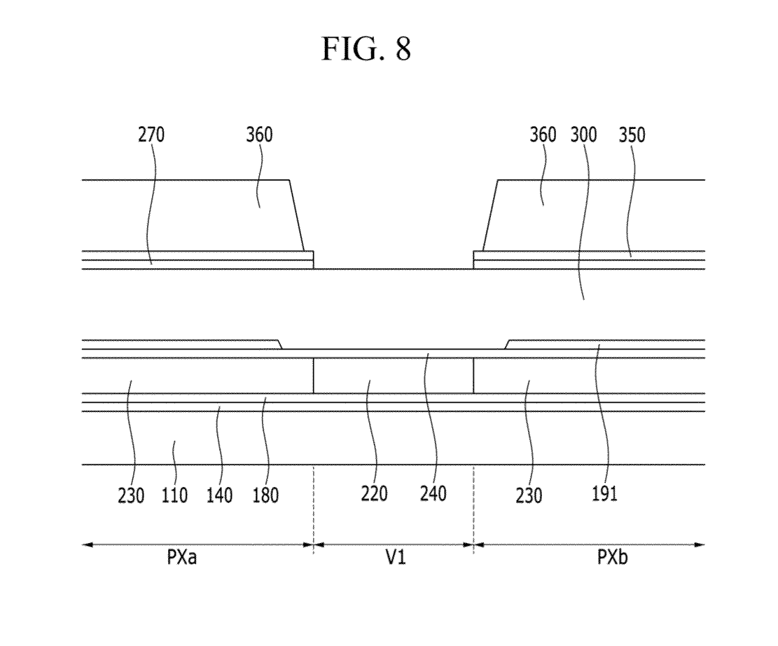

Next, as illustrated in FIG. 8, the second insulating layer 350 and the common electrode 270 are patterned using the roof layer 360 as a mask. First, the second insulating layer 350 is dry-etched using the roof layer 360 as a mask and then the common electrode 270 is wet-etched.

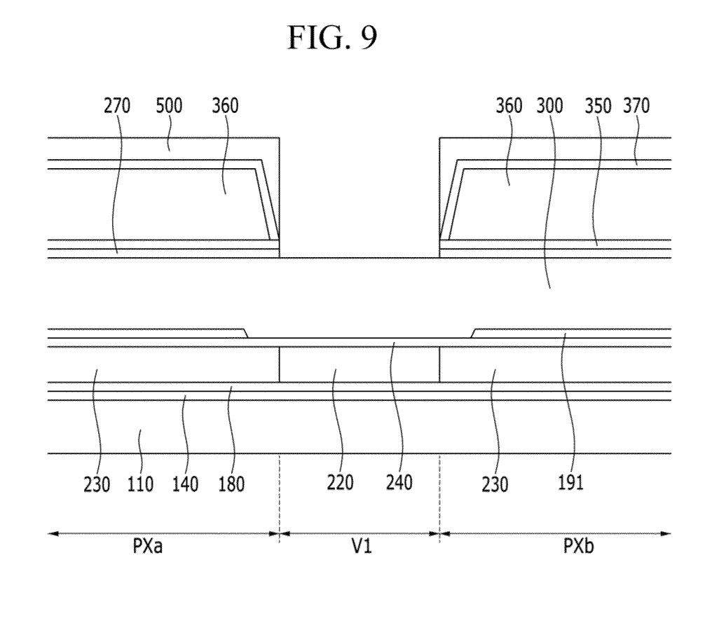

Next, as illustrated in FIG. 9, a third insulating layer 370 made of an inorganic insulating material (such as silicon nitride (SiNx), silicon oxide (SiOx), or silicon oxynitride (SiOxNy)) may be formed on the roof layer 360.

Next, a photoresist 500 is coated on the third insulating layer 370, and the photoresist 500 is patterned by a photolithography process. In this case, a portion of the photoresist 500 positioned at the first valley V1 may be removed. The third insulating layer 370 is etched using the patterned photoresist 500 as a mask. That is, a portion of the third insulating layer 370 positioned at the first valley V1 is removed.

The third insulating layer 370 may be formed covering the upper surface and the side of the roof layer 360 to protect the roof layer 360. The third insulating layer 370 may be positioned outside the roof layer 360.

The second insulating layer 350 may have a same pattern as the third insulating layer 370. In some other embodiments, the second insulating layer 350 may be formed inside the pattern of the roof layer 360. In those other embodiments, the third insulating layer 370 may be formed contacting the second insulating layer 350.

In some instances, an apparatus for patterning the roof layer 360 may be different from an apparatus for patterning the third insulating layer 370, and a difference between the patterns of the third insulating layer 370 and the roof layer 360 may be increased due to alignment differences between the two apparatuses. In those instances, a portion of the third insulating layer 370 positioned outside the roof layer 360 may sag or break, but since the third insulating layer 370 is not a conductive member, the sagging or breaking of the third insulating layer 370 should not create electrical problems (such as a short circuit between the third insulating layer 370 and the pixel electrode 191).

Although the process of forming the third insulating layer 370 has been described above, the inventive concept is not limited thereto. For example, in some particular embodiments, the third insulating layer 370 need not be formed. When the third insulating layer 370 is not formed, misalignment errors between the roof layer 360 and the third insulating layer 370 (due to different patterning apparatuses) can be prevented.

Further, since the second insulating layer 350 and common electrode 270 are patterned using the roof layer 360 as a mask, misalignment between the second insulating layer 350 and common electrode 270 therefore will not occur.

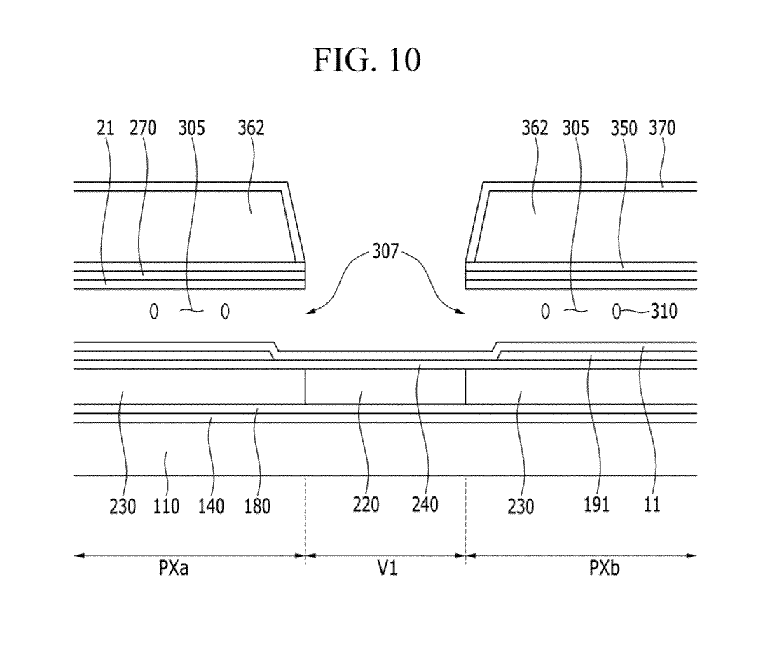

As illustrated in FIG. 10, the sacrificial layer 300 is fully removed by applying a developer or a stripper solution on regions of the substrate 110 where the sacrificial layer 300 is exposed. In some embodiments, the sacrificial layer 300 may be fully removed using an ashing process.

When the sacrificial layer 300 is removed, the microcavity 305 is generated at a site where the sacrificial layer 300 was previously positioned.

The pixel electrode 191 and the common electrode 270 are spaced apart from each other with the microcavity 305 disposed therebetween, and the pixel electrode 191 and the roof layer 360 are spaced apart from each other with the microcavity 305 disposed therebetween. The common electrode 270 and the roof layer 360 are formed covering the upper surface and both sides of the microcavity 305.

The microcavity 305 is exposed to the outside through a portion where the roof layer 360, the third insulation layer 350, and the common electrode 270 are removed (the removed portion being referred to as the injection hole 307). The injection hole 307 may be formed along the first valley V1. For example, a plurality of injection holes 307 may be formed facing each other at the edges of the first subpixel area PXa and the second subpixel area PXb. That is, the injection holes 307 may be disposed corresponding to the lower side of the first subpixel area PXa and the upper side of the second subpixel area PXb so as to expose a side of the microcavity 305. In some embodiments, the injection hole 307 may also be formed along the second valley V2.

Next, the roof layer 360 is cured by applying heat to the substrate 110. The cured roof layer 360 maintains the shape of the space 305.

Next, when an aligning agent containing an alignment material is dispensed on the substrate 110 by a spin coating method or an inkjet method, the aligning agent is injected into the microcavity 305 through the injection hole 307. When the aligning agent is injected into the microcavity 305 and then a curing process is performed, a solution component is evaporated and the alignment material remains on the inner wall of the microcavity 305.

Accordingly, the first alignment layer 11 may be formed on the pixel electrode 191, and the second alignment layer 21 may be formed below the common electrode 270. The first alignment layer 11 and the second alignment layer 21 face each other with the microcavity 305 disposed therebetween and are connected to each other at an edge of the pixel area.

In this case, the first and second alignment layers 11 and 21 may be aligned in a direction perpendicular to the substrate 110, except at the side of the microcavity 305. In addition, a process of irradiating UV light onto the first and second alignment layers 11 and 21 is performed, and as a result, the first and second alignment layers 11 and 21 may be aligned in a direction parallel to the substrate 110.

Next, when the liquid crystal material comprising liquid crystal molecules 310 is dispensed on the substrate 110 by an inkjet method or a dispensing method, the liquid crystal material is injected into the microcavity 305 through the injection hole 307. In this case, the liquid crystal material may be dispensed in the injection holes 307 formed along the odd-numbered first valleys V1 and need not be dispensed in the injection holes 307 formed along the even-numbered first valleys V1. In some other embodiments, the liquid crystal material may be dispensed in the injection holes 307 formed along the even-numbered first valleys V1 and need not be dispensed in the injection holes 307 formed along the odd-numbered first valleys V1.

When the liquid crystal material is dispensed in the liquid crystal injection holes 307 formed along the odd-numbered first valleys V1, the liquid crystal material passes through the liquid crystal injection hole 307 and injects into the microcavity 305 via capillary force. In this case, the liquid crystal material is injected into the microcavity 305 by discharging air in the microcavity 305 through the liquid crystal injection holes 307 formed along the even-numbered first valleys V1.

In some embodiments, the liquid crystal material may be dispensed in all of the injection holes 307. That is, the liquid crystal material may be dispensed in the injection holes 307 formed along the odd-numbered first valleys V1 and the injection holes 307 formed along the even-numbered first valleys V1.

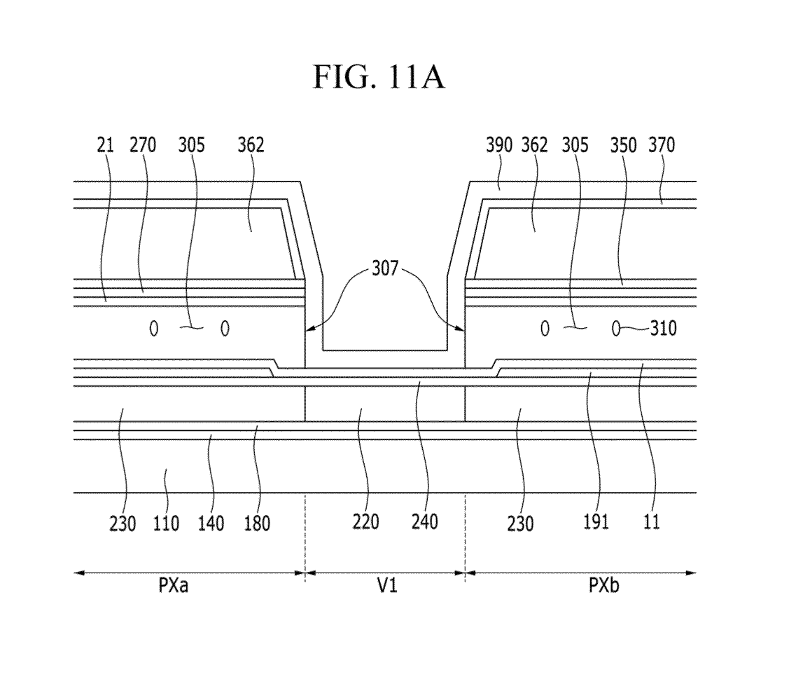

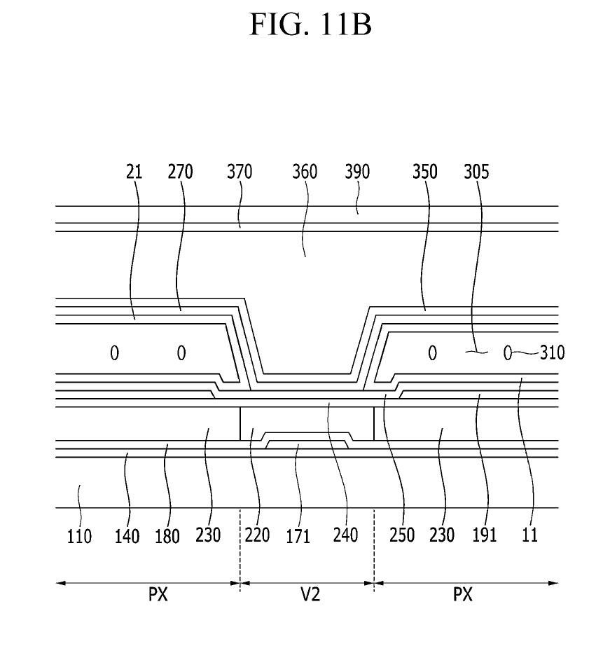

As illustrated in FIG. 11A, an overcoat 390 is formed by depositing a material (which does not react with the liquid crystal molecules 310) on the third insulating layer 370. The overcoat 390 is formed covering the injection hole 307 (where the microcavity 305 is exposed to the outside) so as to seal the microcavity 305.

Further, as illustrated in FIG. 11B, the liquid crystal molecules 310 are filled in the microcavity 305 (where the width varies for each color filter 230 region), and thus a liquid crystal display having a different cell gap for each color filter 230 region may be formed.

Next, although not illustrated, polarizers may be further attached onto the upper and lower surfaces of the display device. The polarizers may include a first polarizer and a second polarizer. The first polarizer may be attached onto the lower surface of the substrate 110, and the second polarizer may be attached onto the overcoat 390.

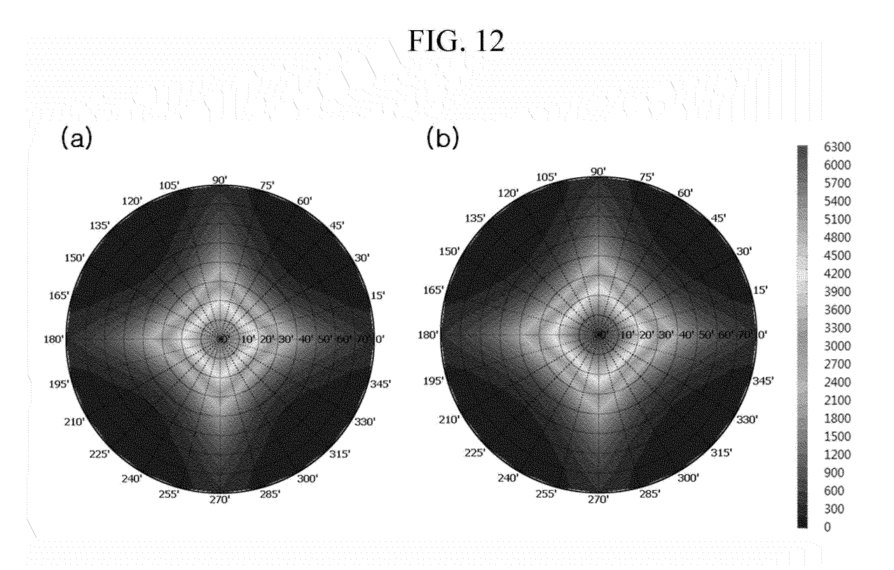

FIG. 12 compares the contrast ratios between an exemplary liquid crystal display and a conventional liquid crystal display. Specifically, the contrast ratio of the exemplary liquid crystal display in FIG. 12(a) is obtained by measuring a liquid crystal display having a different cell gap for each color filter region. On the other hand, the contrast ratio of the conventional liquid crystal display in FIG. 12(b) is obtained by measuring a liquid crystal display having a same cell gap for each color filter region.

Referring to FIG. 12, the contrast ratio of the exemplary liquid crystal display (FIG. 12(a)) is increased by about 25% compared to the conventional liquid crystal display (FIG. 12(b)).

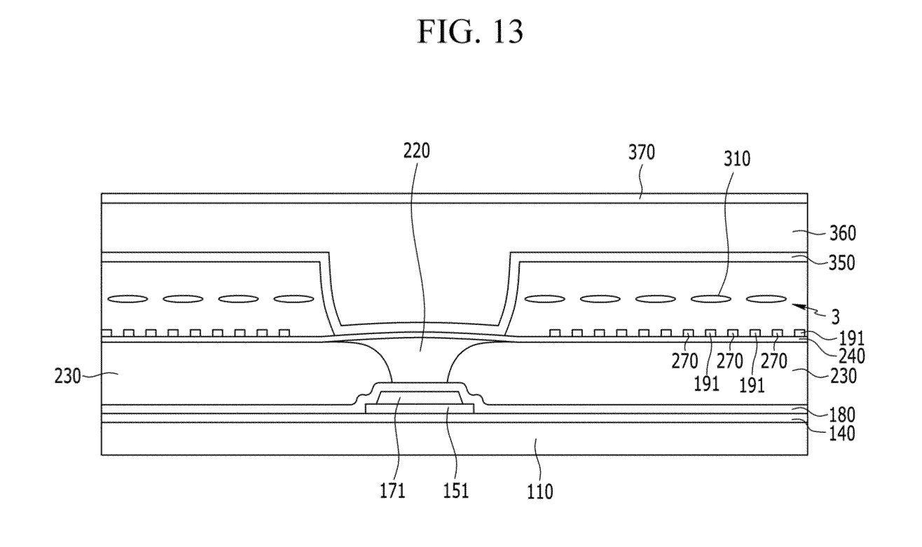

Next, a liquid crystal display according to another exemplary embodiment of the inventive concept will be described in detail with reference to FIG. 13.

FIG. 13 is a cross-sectional view of a liquid crystal display according to another exemplary embodiment of the inventive concept.

Referring to FIG. 13, the common electrode 270 is positioned between the pixel electrodes 191. Unlike the embodiments of FIGS. 1 to 5, the liquid crystal molecules in FIG. 13 may move according to a horizontal electric field.

In each of the different embodiments of the inventive concept described above, since a different cell gap is formed for each color filter to control different transmittance of light for each color filter, a contrast ratio of the liquid crystal display can be improved. Also, since the different transmittance of light may be controlled through the cell gap for each color filter, the voltage controlling unit for controlling the transmittance may be omitted, thereby reducing the manufacturing costs of the liquid crystal display.

While the inventive concept has been described in connection with what is presently considered to be exemplary embodiments, it is to be understood that the inventive concept is not limited to the disclosed embodiments, but, on the contrary, is intended to cover various modifications and equivalent arrangements included within the spirit and scope of the appended claims.

What is claimed is:

1. A liquid crystal display, comprising:
a substrate including a plurality of pixel areas;
a thin film transistor disposed on the substrate in each of the plurality of pixel areas;
a color filter disposed in each of the plurality of pixel areas;
a pixel electrode electrically connected with a drain electrode of the thin film transistor;
a liquid crystal layer positioned on the pixel electrode and filling a microcavity;
a common electrode positioned on the pixel electrode and spaced apart from the pixel electrode by the microcavity;
a roof layer positioned on the common electrode;
an injection hole formed in the common electrode and the roof layer so as to expose a part of the microcavity; and
an overcoat formed on the roof layer so as to cover the injection hole to seal the microcavity,
wherein a height of the liquid crystal layer corresponding to the color filter having a first color is different from a height of the liquid crystal layer corresponding to the color filter having a second color.

2. The liquid crystal display of claim 1, wherein:
red, green, and blue color filters are formed in each pixel area.

3. The liquid crystal display of claim 2, further comprising:
a light blocking member disposed between adjacent color filters.

4. The liquid crystal display of claim 3, wherein:
a height of the liquid crystal layer separately formed on each color filter is defined by the following equation:
$$d = \frac{2}{m {λ}_{cf} Δ {n}_{lc}}$$
where d represents a height of the liquid crystal layer or a cell gap of the liquid crystal layer, λ_{cf} represents a wavelength of light passing through each color filter, Δn_{lc} represents a phase difference of the liquid crystal, and m represents an integer.

5. The liquid crystal display of claim 4, further comprising:
a first insulating layer positioned on the thin film transistor.

6. The liquid crystal display of claim 4, further comprising:
a second insulating layer positioned on the common electrode.

7. The liquid crystal display of claim 4, further comprising:
a first alignment layer and a second alignment layer disposed on the pixel electrode and the common electrode, respectively.

8. The liquid crystal display of claim 7, wherein:
the first alignment layer and the second alignment layer are vertical alignment layers.

9. The liquid crystal display of claim 4, further comprising:
a third insulating layer formed on the roof layer.

10. A method of manufacturing a liquid crystal display, comprising:
forming a thin film transistor on a substrate in each of a plurality of pixel areas;
forming a color filter in each of the plurality of pixel areas;
forming a pixel electrode electrically connected with a drain electrode of the thin film transistor;
forming a sacrificial layer on the pixel electrode so that a height of the sacrificial layer corresponding to the color filter having a first color is different from a height of the sacrificial layer corresponding to the color filter having a second color;
forming a common electrode on the sacrificial layer;
forming a roof layer on the common electrode;
exposing the sacrificial layer;
forming, by removing the exposed sacrificial layer, a microcavity separately for each color filter between the pixel electrode and the common electrode;
forming a liquid crystal layer by injecting a liquid crystal material into the microcavity; and
forming an overcoat on the roof layer to seal the microcavity.

11. The method of claim 10, wherein:
the sacrificial layer is formed by an inkjet method.

12. The method of claim 10, wherein:
red, green, and blue color filters are formed in each pixel area.

13. The method of claim 12, further comprising:
forming a light blocking member between the respective color filters.

14. The method of claim 13, wherein:
a height of the liquid crystal layer separately formed on each color filter is defined by the following equation:
$$d = \frac{2}{m {λ}_{cf} Δ {n}_{lc}}$$
where d represents a height of the liquid crystal layer or a cell gap of the liquid crystal layer, λ_{cf} represents a wavelength of light passing through each color filter, Δn_{lc} represents a phase difference of the liquid crystal, and m represents an integer.

15. The method of claim 14, further comprising:
forming a first insulating layer on the thin film transistor.

16. The method of claim 14, further comprising:
forming a second insulating layer on the common electrode.

17. The method of claim 14, further comprising:
forming a first alignment layer and a second alignment layer on the pixel electrode and the common electrode, respectively.

18. The method of claim 17, wherein:
the first alignment layer and the second alignment layer are vertical alignment layers.

19. The method of claim 14, further comprising:
forming a third insulating layer on the roof layer.
